(19) United States
(12) Patent Application Publication
(10) Pub. No.: US 2011/0053058 A1
(43) Pub. Date: Mar. 3, 2011

(54) SEMICONDUCTOR DEVICE FABRICATION MASK AND METHOD OF MANUFACTURING THE SAME

(76) Inventors: Kyo OTSUBO, Tokyo (JP); Makiko Katano, Yokohama-shi (JP); Haruko Akutsu, Yokosuka-shi (JP); Ayako Mizuno, Yokohama-shi (JP)

(21) Appl. No.: 12/871,193

(22) Filed: Aug. 30, 2010

(30) Foreign Application Priority Data
Aug. 31, 2009 (JP) 2009-201062

(51) Int. Cl. G03F 1/00

(52) U.S. Cl. 430/5

(57) ABSTRACT

According to one embodiment, a semiconductor device fabrication mask comprises a light-transmitting substrate, and a semi-light-shielding pattern and a light-shielding pattern formed on portions of the light-transmitting substrate, wherein the concentration of an S-containing material is 0.4% or less within the range of a depth of 1 nm from the exposed surface of the light-transmitting substrate, the surface of the semi-light-shielding pattern, and the surface of the light-shielding pattern.

### CROSS-REFERENCE TO RELATED APPLICATIONS

This application is based upon and claims the benefit of priority from Japanese Patent Application No. 2009-201062, filed Aug. 31, 2009; the entire contents of which are incorporated herein by reference.

### FIELD

Embodiments described herein relate generally to a mask to be applied to the fabrication of a semiconductor device.

### BACKGROUND

When performing exposure in a lithography step in the fabrication of a semiconductor device, a crystalline or amorphous foreign matter called haze is sometimes produced on the surface of a mask (reticle). If this foreign matter grows, it is transferred as a defect onto a semiconductor wafer. One cause of haze is a slight amount of SO₄ on the mask surface.

SO₄ is left behind on the mask surface by, e.g., sulfuric acid cleaning performed during the mask manufacturing process. This SO₄ reacts with ammonia in, e.g., the atmosphere or with Mo as a halftone film component. This reaction produces, as haze, ammonium sulfate, a compound of sulfuric acid and an Mo oxide, or the like.

As a method of removing the residual SO₄, a method that performs a process such as irradiating the mask surface with UV (UltraViolet) light, annealing the mask surface, or removing the mask surface after sulfuric acid cleaning has been proposed.

Also, a method of suppressing haze by controlling the concentration of SO₄ on the mask surface has been proposed.

Unfortunately, haze is sometimes produced even when removing the residual SO₄ or controlling the concentration of SO₄ on the mask surface by the above-mentioned method.

### BRIEF DESCRIPTION OF THE DRAWINGS

FIG. 1 is a graph showing the SO₄ detection amount of a semiconductor device fabrication mask related to an embodiment;

FIG. 2 is a graph showing the measurement results of TOF-SIMS of the semiconductor device fabrication mask related to the embodiment;

FIG. 3 is a sectional view showing the arrangement of the semiconductor device fabrication mask according to the embodiment; and

FIGS. 4A, 4B, and 4C are views for explaining the principle of control of the concentration of an S-containing material on the semiconductor device fabrication mask according to the embodiment.

### DETAILED DESCRIPTION

In general, according to one embodiment, a semiconductor device fabrication mask comprises a light-transmitting substrate, and a semi-light-shielding pattern and a light-shielding pattern formed on portions of the light-transmitting substrate, wherein the concentration of an S-containing material is 0.4% or less within the range of a depth of 1 nm from the exposed surface of the light-transmitting substrate, the surface of the semi-light-shielding pattern, and the surface of the light-shielding pattern.

An embodiment will be explained below with reference to the accompanying drawing.

As described previously, in order to remove the residual SO₄ on the mask surface in the conventional semiconductor device fabrication mask manufacturing process, the method that performs a process such as irradiating the mask surface with UV light, annealing the mask surface, or removing the mask surface after sulfuric acid cleaning has been proposed. Also, the mask that suppresses haze by controlling the concentration of SO₄ on the surface has been proposed.

Unfortunately, the following problem arises when the above proposals are applied to the manufacture of a mask.

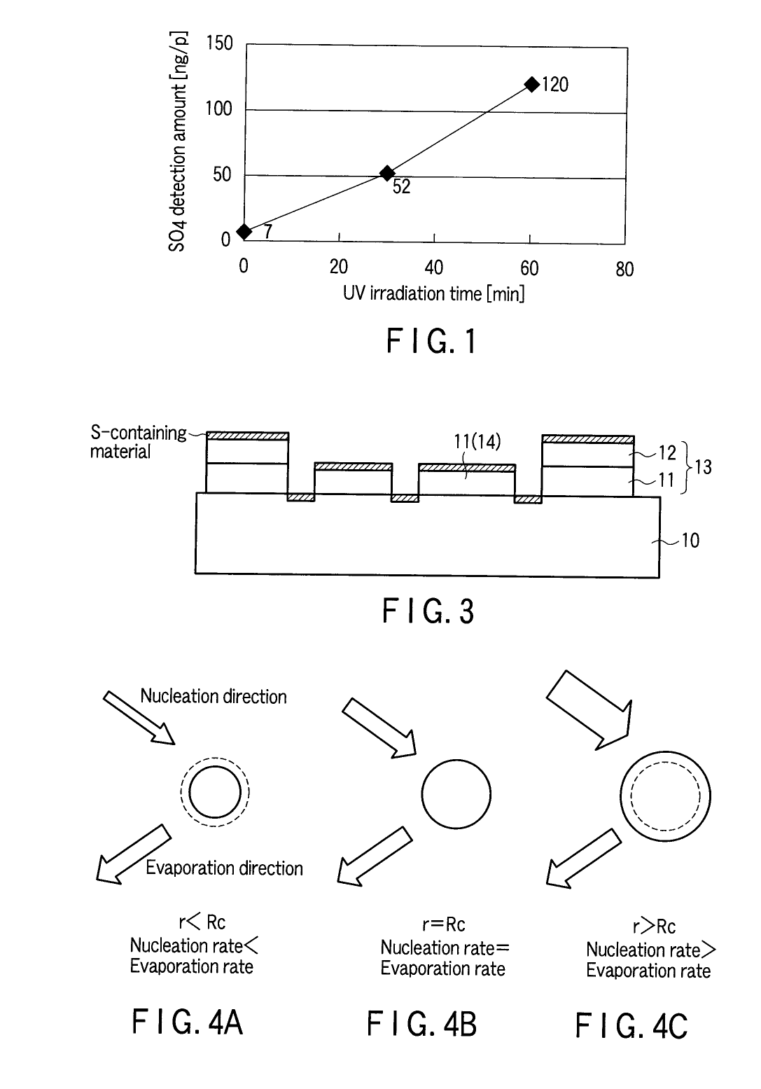

FIG. 1 is a graph showing the change in SO₄ detection amount when a mask is irradiated with UV light. As shown in FIG. 1, UV irradiation increases the SO₄ detection amount. More specifically, when the amount of SO₄ adsorbed on a mask before UV irradiation was measured by the pure water extraction method, the SO₄ detection amount per mask was 7 ng. By contrast, when the measurement was performed by the pure water extraction method after UV irradiation was performed for 30 min, the SO₄ detection amount per mask increased to 52 ng. After irradiation was performed for 60 min, the SO₄ detection amount per mask increased to 120 ng.

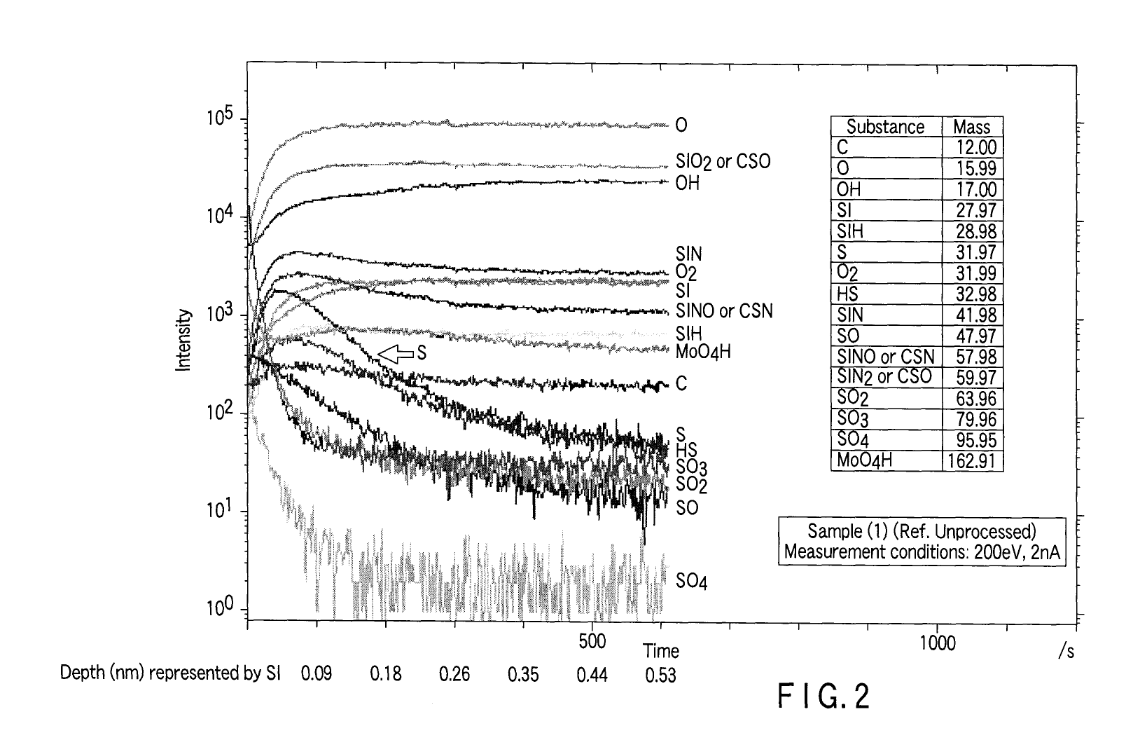

FIG. 2 shows the measurement results of TOF-SIMS in the direction of depth near the surface of a mask (halftone film) before UV irradiation. As shown in FIG. 2, an S impurity exists near the surface of the halftone film before UV irradiation. Note that this S impurity contains not only S but also S oxides such as SO, SO₂, and SO₃ other than SO₄. In the mask manufacturing process, the S impurity is contained in the material (e.g., MoS₂) of No to be used as a halftone film, and mixed in the film. Alternatively, the S impurity existing in a manufacturing apparatus member or in the manufacturing environment adheres to the mask surface in the manufacturing process. This S impurity particularly exists in a region of 0.5 nm from the mask surface.

The results shown in FIGS. 1 and 2 reveal the following. UV irradiation produces O₃. This O₃ oxidizes the S impurity near the mask surface, and generates SO₄. That is, the amount of SO₄ detected after UV irradiation presumably increased by the amount of SO₄ generated from the S impurity on the mask surface.

On the other hand, UV light such as an ArF laser is used in a semiconductor device exposure step. O₃ is produced when oxygen or water in the air in an exposure apparatus is excited by irradiation with the ArF laser. That is, when performing the exposure step by using a mask on the surface of which the S impurity is adhered, SO₄ is produced on the mask and generates haze. To suppress haze, therefore, it is necessary to reduce not only SO₄ but also the S impurity near the mask surface.

In the conventional mask manufacturing process, however, the S impurity is insufficiently controlled and produces haze. Controlling the amount of SO₄ and the S impurity to a certain extent is also a problem.

Accordingly, a semiconductor device fabrication mask according to this embodiment suppresses haze by controlling not only SO₄ but also the S impurity near the surface.

The arrangement of the semiconductor device fabrication mask according to this embodiment will be explained below with reference to FIG. 3.

FIG. 3 shows the structure of the semiconductor device fabrication mask according to this embodiment. As shown in FIG. 3, the semiconductor device fabrication mask includes a light-transmitting substrate 10, light-shielding patterns 13, and semi-light-shielding patterns 14.

On the light-transmitting substrate 10, a semi-light-shielding film (halftone film) 11 is formed in prospective regions of the light-shielding patterns 13 and semi-light-shielding patterns 14. On the semi-light-shielding film 11, a light-shielding film 12 is formed in prospective regions of the light-shielding patterns 13. A pellicle frame and pellicle (neither is shown) are formed as dust-proof members on the semiconductor device fabrication mask thus formed.

The light-transmitting substrate 10 is made of, e.g., quartz. The halftone film 11 is made of, e.g., a compound containing Mo, Si, O, and N, and has a film thickness of, e.g., 70 nm. The light-shielding film 12 is made of, e.g., Cr or CrO.

In this embodiment, slight amounts of an S impurity and SO₄ (to be collectively referred to as an S-containing material hereinafter) exist near the exposed surface of the light-transmitting substrate 10, near the surfaces of the light-shielding patterns 13, and near the surfaces of the semi-light-shielding patterns 14. More specifically, the concentration of the S-containing material is 0.4% or less within the range of a depth of 1 nm from these surfaces. Haze on the mask surface can be suppressed by thus controlling not only the SO₄ concentration but also the concentration of the S impurity.

### <Principle>

The principle of control of the concentration of the S-containing material will be explained below by using equations (1) to (4) below.

ΔG=−(4/3)πr³Δμ+4πr²γ (1)

dΔG/dr=0 (2)

Rc=2γ/Δμ (3)

Δμ=kT logₑp/pₑ (4)

where ΔG is the Gibbs free energy, r is the radius of a droplet, Δμ is the decrease in free energy when one molecule is added, γ is the surface energy, Rc is a critical nuclear radius, k is a Boltzmann constant, T is the temperature, pₑ is the equilibrium vapor pressure, and p is the vapor pressure.

Equation (1) exhibits that as the radius (droplet radius) r of an aggregate of molecules increases, the Gibbs free energy ΔG increases first and then decreases from the critical point. The decrease in Gibbs free energy ΔG indicates stabilization. The radius of this critical point is called the critical nuclear radius Rc. FIGS. 4A, 4B, and 4C are views showing the relationship between the radius r of the aggregate of molecules and the critical nuclear radius Rc. As shown in FIG. 4A, when the radius r of the aggregate of molecules is smaller than the critical nuclear radius Rc, the evaporation direction is larger than the nucleation direction. The nuclei are unstable in this state. On the other hand, as shown in FIG. 4C, when the radius r of the aggregate of molecules is larger than the critical nuclear radius Rc, the nucleation direction is larger than the evaporation direction. The nuclei are stable in this state. That is, when SO₄ molecules aggregate to some extent and the radius r of the aggregate of the molecules becomes larger than the critical nuclear radius Rc, the SO₄ molecules become stable and form a growing foreign matter.

Equation (3) determines the critical nuclear radius Rc. Also, equation (4) derives the decrease Δμ in free energy when one molecule is added, which is indicated by equation (3). That is, when the vapor pressure p of a molecule that causes nucleation is higher than the saturation vapor pressure pₑ, the molecule that causes nucleation stably grows. That is, if SO₄ exists to such an extent that the vapor pressure of SO₄ is higher than the saturation vapor pressure, haze is produced on the mask surface.

As described above, when the vapor pressure of SO₄ on the mask surface is equal to or higher than the saturation vapor pressure in the exposure step, transfer occurs to a wafer and forms an exposure defect. More specifically, when the temperature is 30° C. and the H₂SO₄ concentration is 95%, the saturation vapor pressure is 0.0015 mmHg (see Sulfuric Acid Handbook). That is, when the vapor pressure of SO₄ on the mask surface is 0.0015 mmHg or more in the exposure step, SO₄ molecules adhered on the mask surface are stable and stay on the mask surface. Consequently, SO₄ reacts with ammonium ions or other cations to form a salt, thereby increasing the amount of foreign matter.

As mentioned above, the vapor pressure of SO₄ in the exposure step includes not only SO₄ existing from the beginning but also SO₄ having changed from the S impurity. That is, not only SO₄ existing from the beginning but also the S impurity can be a foreign matter generation source.

When the S impurity is oxidized into SO₄ and the vapor pressure of SO₄ having changed from the S impurity and SO₄ existing from the beginning is equal to or higher than the saturation vapor pressure, SO₄ molecules associate with other fine particles to form liquid fine particles containing SO₄. These fine particles containing SO₄ react with NH₄ or Mo, and form a salt. As a result, a solid compound (foreign matter) containing SO₄ is formed.

In order for particles containing SO₄ to grow into a foreign matter, the concentration of the S-containing material on the mask surface before the exposure step must be equal to or higher than a predetermined density. This necessary density is calculated from the saturation vapor pressure as follows.

As described above, the saturation vapor pressure of H₂SO₄ is 0.0015 mmHg when the temperature is 30° C. and the H₂SO₄ concentration is 95%. However, the temperature at which the mask is stored is lower than 30° C. Therefore, the actual saturation vapor pressure is the saturation vapor pressure taken when the temperature is 30° C. or lower, and is a value lower than 0.0015 mmHg. Under the circumstances, the vapor pressure of SO₄ on the mask surface must be kept equal to or lower than 0.0015 mmHg.

Also, the molecular weight of a sulfuric acid molecule is larger than that of air. Therefore, sulfuric acid molecules readily stay in a portion surrounded by the mask, pellicle, and pellicle frame. That is, when SO₄ is vaporized on the mask surface and in the space of the surrounded portion, the vapor pressure of SO₄ must be held at least 0.0015 mmHg or less.

If the concentration of the S-containing material is 0.4% within the range of a depth of 1 nm from the mask surface, SO₄ reaches the above-mentioned vapor pressure. That is, to form no haze, the concentration of the S-containing material must be 0.4% or less within the range of a depth of 1 nm from the mask surface.

In addition, to form no haze when the S-containing material exits within the range of a depth of 10 nm from the mask surface, the concentration of the S-containing material must be 0.4% or less within the range of a depth of 1 nm from the mask surface, and 0.04% or less within the range of a depth of 10 nm from the mask surface.

Furthermore, if the S-containing material exists within the range of a depth of 30 nm from the mask surface, the mask itself does not function any longer in some cases. Therefore, under the concentration conditions within the range of a depth of 10 nm from the mask surface as described above, the concentration of the S-containing material must be 0.01% or less within the range of a depth of 30 nm from the mask surface. In this case, however, the concentration of the S-containing material is desirably held at 0.005%, which is 50% of the above condition, due to various factors.

Note that the concentration of the S-containing material is preferably lower in all these cases. Note also that the concentration of the S-containing material on particularly the exposed light-transmitting substrate 10 is preferably lower.

### <Manufacturing Methods>

Examples of a method of manufacturing the semiconductor device fabrication mask according to this embodiment will be explained below. Note that the process of manufacturing the mask shown in FIG. 3 is well known, so a repetitive explanation will be omitted.

### [Manufacturing Method 1]

Manufacturing method 1 is a method of removing the mask surface at the end of the mask manufacturing process. That is, the semi-light-shielding patterns 14 and light-shielding patterns 13 are formed on portions of the light-transmitting substrate 10, and the exposed surface of the light-transmitting substrate 10, the surfaces of the semi-light-shielding patterns 14, and the surfaces of the light-shielding patterns 13 are removed, thereby setting the concentration of the S-containing material at 0.4% or less within the range of a depth of 1 nm from the exposed surface of the light-transmitting substrate 10, the surfaces of the semi-light-shielding patterns 14, and the surfaces of the light-shielding patterns 13. More specifically, the mask surface is removed by about 1 nm by performing etching by, e.g., RIE (Reactive Ion Etching). As shown in FIG. 2, the S impurity exists on the mask surface. Therefore, the S impurity can efficiently be removed by etching the mask surface.

Note that the method of etching the mask surface is not limited to RIE and can also be, e.g., an acceleration cleaning method, a method using an etchant, a polishing method, an ion beam processing method, or a laser evaporation method.

Also, as shown in FIG. 2, the S impurity particularly exists within the range of a depth of 0.5 nm from the mask surface. Accordingly, the mask surface need only be removed by at least about 0.5 nm.

### [Manufacturing Method 2]

Manufacturing method 2 is a method using a material not containing any S impurity, as the raw material of the halftone film. More specifically, PbMoO₄ is used as the raw material of Mo as the material of the halftone film. Conventionally, MoS₂ is used as the raw material of Mo. Therefore, the completed halftone film contains an S impurity. The S impurity can be reduced by thus using a material not containing any S impurity as the raw material of Mo.

### [Manufacturing Method 3]

Manufacturing method 3 is a method of performing UV irradiation and performing pure water cleaning after that at the end of the mask manufacturing process. That is, the semi-light-shielding patterns 14 and light-shielding patterns 13 are formed on portions of the light-transmitting substrate 10, and the exposed surface of the light-transmitting substrate 10, the surfaces of the semi-light-shielding patterns 14, and the surfaces of the light-shielding patterns 13 are irradiated with UV light and cleaned with pure water after that, thereby setting the concentration of the S-containing material at 0.4% or less within the range of a depth of 1 nm from the exposed surface of the light-transmitting substrate 10, the surfaces of the semi-light-shielding patterns 14, and the surfaces of the light-shielding patterns 13. The S impurity on the mask surface forms a CₓH_{y}O_{z}S compound bonding to an organic substance or a compound bonding to an Mo oxide on the mask surface. This makes the S impurity sparingly soluble in pure water. UV irradiation breaks the bond of the compound, and makes the compound readily soluble in pure water. Therefore, the S impurity can efficiently be removed.

### [Manufacturing Method 4]

Manufacturing method 4 is a method of performing annealing and performing pure water cleaning after that at the end of the mask manufacturing process. That is, the semi-light-shielding patterns 14 and light-shielding patterns 13 are formed on portions of the light-transmitting substrate 10, and the exposed surface of the light-transmitting substrate 10, the surfaces of the semi-light-shielding patterns 14, and the surfaces of the light-shielding patterns 13 are annealed and cleaned with pure water after that, thereby setting the concentration of the S-containing material at 0.4% or less within the range of a depth of 1 nm from the exposed surface of the light-transmitting substrate 10, the surfaces of the semi-light-shielding patterns 14, and the surfaces of the light-shielding patterns 13. More specifically, annealing is performed in an inert gas ambient or air ambient. The annealing temperature is desirably 150° C. or less in consideration of the heat resistance of the mask material. Since heating makes the S impurity readily soluble in pure water, the S impurity can efficiently be removed.

Note that the conditions of manufacturing methods 1 to 4 are appropriately determined such that the concentration of the S-containing material on the mask surface is 0.4% or less. Note also that the steps may be performed by combining any of manufacturing methods 1 to 4.

### <Effects>

In the embodiment described above, the semiconductor device fabrication mask has the structure in which the light-shielding patterns 13 and semi-light-shielding patterns 14 are formed on the light-transmitting substrate 10. The concentration of the S impurity and SO₄ is 0.4% or less within the range of a depth of 1 nm from the surfaces of the light-shielding patterns 13 and semi-light-shielding patterns 14 and the exposed surface of the light-transmitting substrate 10. That is, the concentration of not only SO₄ but also the S impurity is controlled. Even when the S impurity is oxidized to increase the amount of SO₄ in the exposure step, therefore, the vapor pressure of SO₄ can be decreased to 0.0015 mmHg or less. By making the vapor pressure of SO₄ equal to or lower than the saturation vapor pressure, it is possible to prevent SO₄ from changing into a growing foreign matter. This makes it possible to prevent defects caused by the foreign matter, and prolong the mask life.

Also, oxidation occurs in an exposure apparatus when the concentration of SO₄ increases in the exposure step. In addition, HF is produced from H₂SO₄ and calcium fluoride or magnesium fluoride, and corrodes optical parts and the interior of the exposure apparatus. This problem can also be solved by controlling the concentration of the S impurity in addition to that of SO₄.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device fabrication mask comprising:
a light-transmitting substrate; and
a semi-light-shielding pattern and a light-shielding pattern formed on portions of the light-transmitting substrate,
wherein a concentration of an S-containing material is not more than 0.4% within a range of a depth of 1 nm from an exposed surface of the light-transmitting substrate, a surface of the semi-light-shielding pattern, and a surface of the light-shielding pattern.

2. The mask according to claim 1, wherein the concentration of the S-containing material is not more than 0.04% within the range of a depth of 10 nm from the exposed surface of the light-transmitting substrate, the surface of the semi-light-shielding pattern, and the surface of the light-shielding pattern.

3. The mask according to claim 1, wherein the concentration of the S-containing material is not more than 0.01% within the range of a depth of 30 nm from the exposed surface of the light-transmitting substrate, the surface of the semi-light-shielding pattern, and the surface of the light-shielding pattern.

4. The mask according to claim 1, wherein the concentration of the S-containing material is not more than 0.005% within the range of a depth of 30 nm from the exposed surface of the light-transmitting substrate, the surface of the semi-light-shielding pattern, and the surface of the light-shielding pattern.

5. The mask according to claim 1, wherein the S-containing material comprises S and an S oxide.

6. The mask according to claim 5, wherein the S oxide comprises SO, SO₂, SO₃, and SO₄.

7. The mask according to claim 1, wherein the light-transmitting substrate comprises quartz.

8. The mask according to claim 1, wherein the semi-light-shielding pattern comprises a compound containing Mo, Si, O, and N.

9. The mask according to claim 1, wherein the light-shielding pattern comprises one of the Cr and CrO.

10. A method of manufacturing a semiconductor device fabrication mask, comprising:
forming a semi-light-shielding pattern and a light-shielding pattern on portions of a light-transmitting substrate; and
setting a concentration of an S-containing material at not more than 0.4% within a range of a depth of 1 nm from an exposed surface of the light-transmitting substrate, a surface of the semi-light-shielding pattern, and a surface of the light-shielding pattern.

11. The method according to claim 10, wherein the concentration of the S-containing material is set at not more than 0.4% within the range of a depth of 1 nm from the exposed surface of the light-transmitting substrate, the surface of the semi-light-shielding pattern, and the surface of the light-shielding pattern, by removing the exposed surface of the light-transmitting substrate, the surface of the semi-light-shielding pattern, and the surface of the light-shielding pattern.

12. The method according to claim 11, wherein the exposed surface of the light-transmitting substrate, the surface of the semi-light-shielding pattern, and the surface of the light-shielding pattern are removed by 0.5 nm to 1 nm.

13. The method according to claim 10, wherein the concentration of the S-containing material is set at not more than 0.4% within the range of a depth of 1 nm from the exposed surface of the light-transmitting substrate, the surface of the semi-light-shielding pattern, and the surface of the light-shielding pattern, by irradiating the exposed surface of the light-transmitting substrate, the surface of the semi-light-shielding pattern, and the surface of the light-shielding pattern with UV light, and cleaning the exposed surface of the light-transmitting substrate, the surface of the semi-light-shielding pattern, and the surface of the light-shielding pattern with pure water thereafter.

14. The method according to claim 10, wherein the concentration of the S-containing material is set at not more than 0.4% within the range of a depth of 1 nm from the exposed surface of the light-transmitting substrate, the surface of the semi-light-shielding pattern, and the surface of the light-shielding pattern, by annealing the exposed surface of the light-transmitting substrate, the surface of the semi-light-shielding pattern, and the surface of the light-shielding pattern, and cleaning the exposed surface of the light-transmitting substrate, the surface of the semi-light-shielding pattern, and the surface of the light-shielding pattern with pure water thereafter.

15. The method according to claim 14, wherein the annealing is performed at not more than 150° C.
